(19) United States
(12) Patent Application Publication
(10) Pub. No.: US 2012/0048339 A1
(43) Pub. Date: Mar. 1, 2012

(54) MULTI-JUNCTION GROUP III-V COMPOUND SEMICONDUCTOR SOLAR CELL AND FABRICATION METHOD THEREOF

(75) Inventors: YI-AN CHANG, HSINCHU HSIEN (TW); LI-WEN LAI, HSINCHU HSIEN (TW); LI-HUNG LAI, HSINCHU HSIEN (TW)

(73) Assignee: MILLENNIUM COMMUNICATION CO., LTD., HSINCHU HSIEN (TW)

(21) Appl. No.: 12/948,062

(22) Filed: Nov. 17, 2010

(30) Foreign Application Priority Data
Aug. 31, 2010 (TW) 99129253

(51) Int. Cl. H01L 31/052; H01L 31/18

(52) U.S. Cl. 136/246; 438/74; 438/72; 257/E31.119; 257/E31.032

(57) ABSTRACT

A multi-junction group III-V compound semiconductor solar cell and fabrication method thereof forms a 2D photonic crystal structure in the topmost window layer of the stacked solar cell units by etching holes in the window layer. The 2D photonic crystal structure causes omni-directional reflection of the sunlight along any transverse plane of the 2D photonic crystal structure and directs the oblique sunlight to enter the bottom surface of the holes, thereby increasing the amount of incident light. By applying the property that the 2D photonic crystal structure causes a wider range of wavelengths to have higher transmission efficiency at the window layer to the multi-junction group III-V compound semiconductor solar cell, energy conversion efficiency may be effectively increased.

### BACKGROUND OF THE INVENTION

1. Field of the Invention

The present invention relates to a solar cell and the fabrication method thereof, and more particularly to a multi-junction group III-V compound semiconductor solar cell and the fabrication method thereof.

2. Description of the Prior Art

FIG. 1 schematically illustrates an elevation view of a prior art solar cell. As illustrated in the figure, the prior art solar cell includes a substrate 110; a solar cell unit 120 formed on the substrate 110, wherein a top layer of the solar cell unit 120 is a window layer 130; a bottom electrode 100 disposed on the bottom of the substrate 110; a top electrode 150 covering a portion of the window layer 130; and an anti-reflective coating 140 covering the portion of the window layer 130 not covered by the top electrode 150.

Generally speaking, when the solar energy is incident onto the surface of the solar cell, it needs to transmit through the anti-reflective coating 140 and the window layer 130 before it can reach the solar cell unit 120, and the solar energy reaching the solar cell unit 120 cannot be less than the energy band gap of an absorption layer of the solar cell unit 120 for the photovoltaic effect to take place, converting the solar energy into electric energy to be stored. However, the incident angle of the sunlight to the ground changes with the time of a day and the seasons of a year. When the sunlight is more oblique, it is very likely that it will miss the solar cell.

Therefore, it is highly desirable to be able to direct the non-normal sunlight into the solar cell and increase the transmission efficiency of the sunlight at the window layer that can be effectively absorbed to enhance the energy conversion efficiency.

### SUMMARY OF THE INVENTION

The present invention is directed to a multi-junction group III-V compound semiconductor solar cell and the fabrication method thereof. By etching a plurality of holes in the topmost window layer of a plurality of solar cell units stacked together, the window layer forms a 2-dimensional photonic crystal structure that omni-directionally reflects sunlight along any transverse plane, thereby directing the non-normal sunlight into the solar cell units. Because the plurality of solar cell units respectively absorb sunlight within different ranges of wavelength, and the window layer offers a better transmission efficiency for a larger wavelength range of the sunlight, the energy conversion efficiency of the multi-junction group III-V compound semiconductor solar cell may be effectively increased.

An embodiment of the present invention provides a fabrication method of a multi-junction group III-V compound semiconductor solar cell including forming a plurality of solar cell units stacked together, respectively for absorbing light waves within different ranges of wavelength, and any two of the solar cell units are connected with each other via an intermediate layer, wherein the topmost layer and the bottommost layer of the stacked solar cell units are a window layer and a substrate, respectively; downward etching the window layer to form a plurality of holes, so that the window layer forms a 2-dimensional photonic crystal structure omni-directionally reflecting the sunlight along any transverse plane; forming a bottom electrode on a bottom surface of the substrate; and forming a top electrode on a portion of the window layer. According to an embodiment, the thickness of the window layer is between 200 nm to 500 nm.

Another embodiment of the present invention provides a multi-junction group III-V compound semiconductor solar cell including a plurality of solar cell units stacked together, respectively for absorbing light waves within different ranges of wavelength, and any two of the solar cell units are connected with each other via an intermediate layer, wherein the topmost layer and the bottommost layer of the stacked solar cell units are a window layer and a substrate, respectively; a bottom electrode disposed on a bottom surface of the substrate; and a top electrode disposed on a portion of the window layer. The window layer has a plurality of holes so that the window layer forms a 2-dimensional photonic crystal structure omni-directionally reflecting the sunlight along any transverse plane. According to an embodiment, the thickness of the window layer is between 200 nm to 500 nm.

The objective, technologies, features and advantages of the present invention will become more apparent from the following description in conjunction with the accompanying drawings, wherein certain embodiments of the present invention are set forth by way of illustration and examples.

### BRIEF DESCRIPTION OF THE DRAWINGS

FIG. 1 schematically illustrates an elevation view of a prior art solar cell;

FIG. 2 schematically illustrates an elevation view of the multi-junction group III-V compound semiconductor solar cell according to an embodiment of the present invention;

FIGS. 3a, 3b and 3c schematically illustrate sectional views of the window layer receiving sunlight at different incident angles, respectively;

FIG. 4 schematically illustrates a correlation diagram of the transmission efficiency Eff of the window layer and the wavelength 2; and

FIG. 5 schematically illustrates an absorption spectrum of the multi-junction group III-V compound semiconductor solar cell according to an embodiment of the present invention.

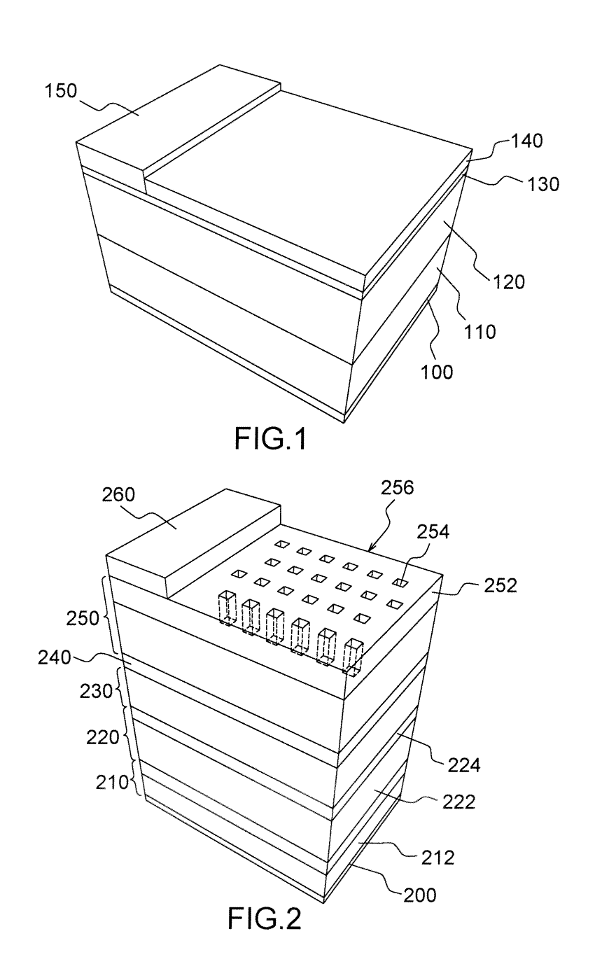

### DESCRIPTION OF THE PREFERRED EMBODIMENT

FIG. 2 schematically illustrates an elevation view of a multi-junction group III-V compound semiconductor solar cell according to an embodiment. The multi-junction group III-V compound semiconductor solar cell includes a plurality of solar cell units 210, 230, 250 stacked together, respectively for absorbing light waves within different ranges of wavelength, and any two of the solar cell units 210 and 230, and 230 and 250 are connected with each other via an intermediate layer 220, 240, wherein the topmost layer and the bottommost layer of the stacked solar cell units 210, 230 and 250 are respectively a window layer 252 and a substrate 212; a plurality of bottom electrode 200 disposed on a bottom surface (not illustrated) of the substrate 212; and a top electrode disposed on a portion of the window layer 252. The window layer 252 has a plurality of holes 254 so that the window layer 252 forms a 2-dimensional (2D) photonic crystal structure 256 omni-directionally reflecting the sunlight along any transverse plane.

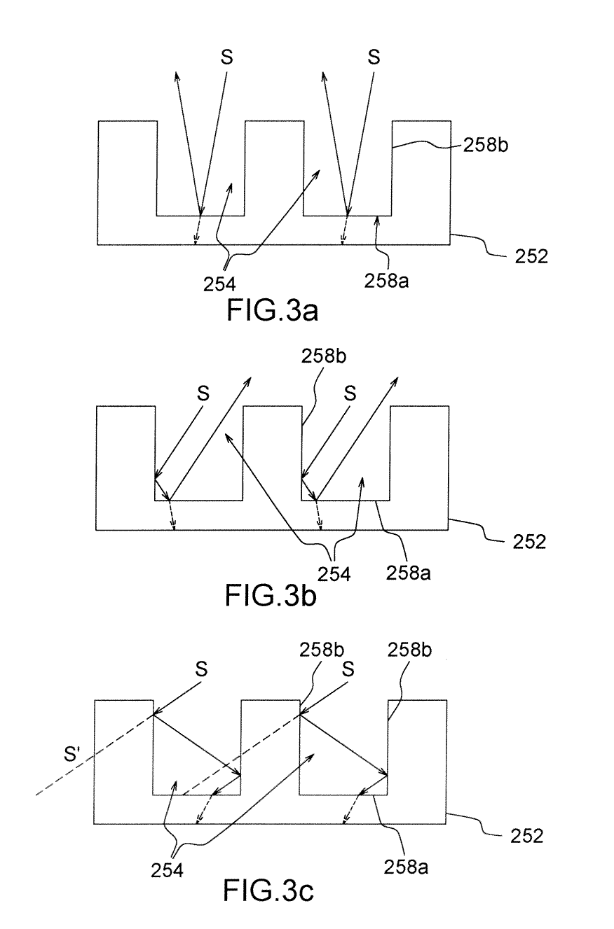

Referring to FIG. 2, the 2D photonic crystal structure 256 is composed of materials with different refractive indices in 2D periodic arrangement, forming a photonic band gap where light waves within a corresponding range of wavelength may not propagate along any direction along any transverse plane of the 2D photonic crystal structure 256, namely the omni-directional reflection. Hence, the 2D photonic crystal structure 256 may direct the non-normal sunlight into the solar cell units 210, 230, 250. FIG. 3a, 3b, 3c schematically illustrate sectional views of the window layer 252 receiving sunlight S at different incident angles, respectively. For example, as shown in FIG. 3a, when the incident angle of the sunlight S is 5°, the sunlight S may be directly incident onto a bottom surface 258a of the hole 254; as shown in FIG. 3b, when the incident angle of the sunlight S is 35°, the sunlight S is incident onto the side surface 258b of the hole 254, and is reflected because of the omni-directional reflective property of the 2D photonic crystal structure 256 to enter the bottom surface 258a of the hole 254; as shown in FIG. 3c, when the incident angle of the sunlight S is 75°, a portion of the sunlight S′ which cannot enter the solar cell unit 210, 230, 250 originally is reflected by the side surface 258b of the hole 254 due to the omni-directional reflective property of the 2D photonic crystal structure 256 back to the hole 254, and is directed to the bottom surface 258a after multiple reflections between the side surfaces 258b of the hole 254.

Referring to FIG. 2, according to an embodiment, in order for the window layer 252 to form the 2D photonic crystal structure 256, the thickness of the window layer 252 is between 200 nm˜500 nm. According to an embodiment, the hole 262 may be of a column shape or tapered shape, such as rectangular column, pyramid, cylinder or cone, etc. According to an embodiment, the material of the window layer 262 includes an alloy of AlInP. According to an embodiment, the multi-junction group III-V compound semiconductor solar cell further includes an anti-reflective coating (ARC) (in order to reveal the photonic crystal structure 256, the ARC is not illustrated in FIG. 2), covering the portion of the window layer 252 not covered by the top electrode 260, and filling the holes 254.

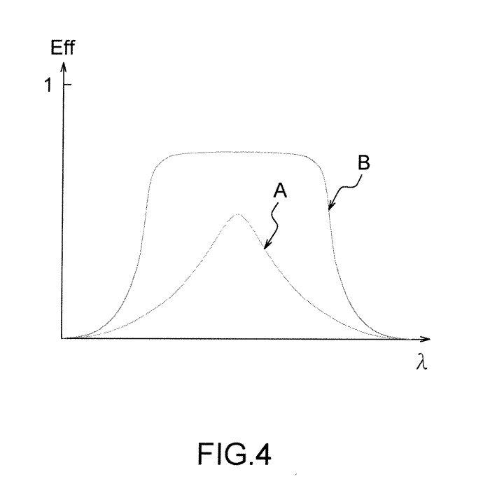

Referring to FIG. 2, according to an embodiment, the 2D photonic crystal structure 256 is designed such that the photonic band gap targets sunlight within a specific range of wavelength that matches with those may be absorbed by the solar cell units 210, 230, 250. As such, the light waves within the specific range of wavelength cannot propagate along the 2D photonic crystal structure, thereby increasing the amount of sunlight within the specific range of wavelength transmitting downward through the window layer 252. FIG. 4 schematically illustrates a correlation diagram of the transmission efficiency Eff of the window layer and the wavelength λ, wherein the transmission efficiency Eff is defined to be the amount of incident light over the amount of downward transmitted light through the window layer 252. Curves A and B in FIG. 4 represent the transmission efficiency of the window layer without and with the 2D photonic crystal structure, respectively. As shown in FIG. 4, for the window layer without the 2D photonic crystal structure, only a smaller range of wavelength has higher transmission efficiency because more light is being trapped to propagate along the lateral direction of the window layer. On the other hand, for the window layer with the 2D photonic crystal structure, a larger range of wavelength has higher transmission efficiency for the light that cannot transmit laterally along the window layer.

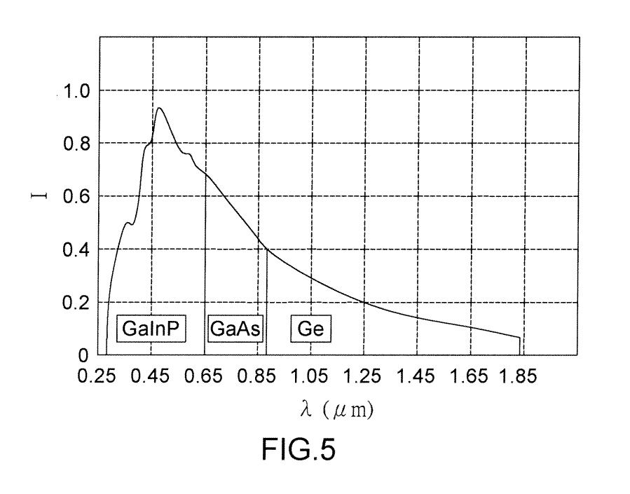

Referring to FIG. 2, according to an embodiment, the stacked solar cell units include a bottom solar cell unit 210 including a bottom PN junction made of Ge; a middle solar cell unit 230 including a middle PN junction made of an alloy of GaAs; and a top solar cell unit 250 including a top PN junction made of an alloy of GaInP. FIG. 5 schematically illustrates the absorption spectrum of the multi-junction group III-V compound semiconductor solar cell according to the aforementioned embodiment, wherein the horizontal axis represents the wavelength λ (μm), and the vertical axis represents the normalized intensity I. As shown in the figure, the bottom solar cell unit 210, middle solar cell unit 230 and top solar cell unit 250 respectively absorb light waves within different ranges, of wavelength. Therefore, by designing the 2D photonic crystal structure 256 that downward propagates sunlight within the range of wavelength matching with the solar cell units 210, 230, 250, energy conversion efficiency may be effectively enhanced.

Referring to FIG. 2, according to an embodiment, the intermediate layer 220 closest to the substrate 212 includes a tunnel junction layer 224 for connecting the solar cell unit 210 and 230. Also, according to an embodiment, the intermediate layer 220 further includes a buffer layer 222 for reducing lattice mismatch. According to an embodiment, the intermediate layer 240 is a tunnel junction layer for connecting the solar cell unit 230 and 250.

Referring to FIG. 2, the fabrication method of the multi-junction group III-V compound semiconductor solar cell according to an embodiment includes the following steps. A plurality of solar cell units 210, 230, 250 are stacked together, respectively for absorbing light waves within different ranges of wavelength, and any two of the solar cell units 210 and 230, and 230 and 250 are connected with each other via an intermediate layer 220, 240, wherein the topmost layer and the bottommost layer of the stacked solar cell units 210, 230, and 250 are a window layer 252 and a substrate 212, respectively. A window layer 252 is downward etched, forming a plurality of holes 254 therein so that the window layer 252 becomes a 2D photonic crystal structure 256 that omni-directionally reflects sunlight along any transverse plane. A bottom electrode 200 is disposed on a bottom surface (not illustrated) of the substrate 212, and a top electrode 260 is formed on a portion of the window layer 252. According to an embodiment, the fabrication method of the multi-junction group III-V compound semiconductor solar cell further includes a step of forming an anti-reflectively coating not illustrated) covering the portion of the window layer 252 not covered by the top electrode 260 and filling the holes 254.

Referring to FIG. 2, the window layer 252 can be formed by molecular beam epitaxy (MBE), liquid phase epitaxy (LPE) or metal-organic chemical vapor deposition (MOCVD), etc. The hole 254 can be formed by anisotropic wet etching or anisotropic dry etching. According to an embodiment, the anisotropic dry etching method is reactive ion etching (RIE).

In conclusion, the present invention provides a multi-junction group III-V compound semiconductor solar cell and the fabrication method thereof. By etching holes in the window layer, the window layer forms a 2D photonic crystal structure that omni-directionally reflects sunlight along any transverse plane, thereby directing the non-normal sunlight into the solar cell effectively. In addition, since the window layer with the 2D photonic crystal structure achieves better transmission efficiency for a larger range of wavelength, multi-junction solar cells are used in the embodiments of the present invention to increase the absorption of sunlight within different ranges of wavelength, effectively increasing the energy conversion efficiency.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A fabrication method of a multi-junction group III-V compound semiconductor solar cell comprising:
forming a plurality of solar cell units stacked together, respectively for absorbing light waves within different ranges of wavelength, and any two of the solar cell units are connected with each other via an intermediate layer, wherein the topmost layer and the bottom most layer of the stacked solar cell units are a window layer and a substrate, respectively;
downward etching the window layer to form a plurality of holes, so that the window layer forms a 2-dimensional photonic crystal structure omni-directionally reflecting the sunlight along any transverse plane;
forming a bottom electrode on a bottom surface of the substrate; and
forming a top electrode on a portion of the window layer.

2. The fabrication method according to claim 1, wherein the method of forming the window layer can be molecular beam epitaxy (MBE), liquid phase epitaxy (LPE) or metal-organic chemical vapor deposition (MOCVD).

3. The fabrication method according to claim 1, wherein the holes are formed by anisotropic wet etching or anisotropic dry etching.

4. The fabrication method according to claim 1, further comprising an anti-reflective coating covering a portion of the window layer.

5. A multi-junction group III-V compound semiconductor solar cell, comprising:
a plurality of solar cell units stacked together, respectively for absorbing light waves within different ranges of wavelength, and any two of the solar cell units are connected with each other via an intermediate layer, wherein the topmost layer and the bottommost layer of the stacked solar cell units are a window layer and a substrate, respectively; and the window layer comprises a plurality of holes so that the window layer forms a 2-dimensional photonic crystal structure omni-directionally reflecting the sunlight along any transverse plane;
a bottom electrode disposed on a bottom surface of the substrate; and
a top electrode disposed on a portion of the window layer.

6. The multi-junction group III-V compound semiconductor solar cell according to claim 5, wherein the thickness of the window layer is between 200 nm to 500 nm.

7. The multi-junction group III-V compound semiconductor solar cell according to claim 5, wherein the material of the window layer comprises an alloy of AlInP.

8. The multi-junction group III-V compound semiconductor solar cell according to claim 5, wherein the hole of the window layer is of a column shape or a tapered shape.

9. The multi-junction group III-V compound semiconductor solar cell according to claim 5, further comprising an anti-reflective coating covering the window layer.

10. The multi-junction group III-V compound semiconductor solar cell according to claim 5, wherein the solar cell units comprises:
a bottom solar cell unit comprising a bottom PN junction, wherein the material of the bottom PN junction comprises Ge;
a middle solar cell unit comprising a middle PN junction, wherein the material of the middle PN junction comprises an alloy of GaAs; and
a top solar cell unit comprising a top PN junction, wherein the material of the top PN junction comprises an alloy of GaInP.
